(19) United States
(12) Patent Application Publication
(10) Pub. No.: US 2015/0004776 A1
(43) Pub. Date: Jan. 1, 2015

(54) POLYSILICON LAYER PREPARING METHOD

(71) Applicant: EverDisplay Optronics (Shanghai) Limited, Shanghai (CN)

(72) Inventors: YuChun YEH, Shanghai (CN); MinChing HSU, Shanghai (CN)

(21) Appl. No.: 14/296,123

(22) Filed: Jun. 4, 2014

(30) Foreign Application Priority Data
Jun. 27, 2013 (CN) 201310264674.8

(51) Int. Cl. H01L 21/02

(52) U.S. Cl. CPC H01L 21/02532; H01L 21/02592; H01L 21/02675
USPC 438/479

(57) ABSTRACT

The present disclosure discloses a method of preparing the polysilicon layer, wherein by the depositions of the amorphous silicon thin film in batches for many times and the implementation of the excimer laser process after each deposition, it can not only convert the amorphous silicon thin film into the polysilicon thin film completely, but also control the uniformity of the polysilicon thin film, thereby gaining the polysilicon layer of good uniformity which composed of the polysilicon thin films stacked in sequence, improving the performance of the product while effectively avoiding the chromatism problems of the display device, and significantly improving the yield of products.

### CROSS-REFERENCE TO RELATED APPLICATIONS

The present application claims priority to and the benefit of Chinese Patent Application No. CN 201310264674.8, filed on Jun. 27, 2013, the entire content of which is incorporated herein by reference.

### BACKGROUND OF THE INVENTION

1. Field of the Invention

The present disclosure relates to the technical field of manufacturing the semiconductor, more specifically, to a polysilicon layer preparing method.

2. Description of the Related Art

With the rapid development of modern life, the high-tech products such as the video products, particularly the digital video or the image devices, come into people's life more commonly. The display is an indispensable part of these digital videos or image devices to show the related information. Users can read information by the display or further control the operation of the device.

The thin film transistor can be applied to the driving components of liquid crystal display, which makes the liquid crystal display become the mainstream of the flat panel display of table straight type and the dominant product of future in the markets of personal laptop computers, game consoles, monitors and so on. Presently, as the amorphous silicon thin film can be grown in the low temperature environment of 200° C. to 300° C., the amorphous silicon thin film transistor is widely used. However, due to the low electron mobility of the amorphous silicon, the amorphous silicon thin film transistor has failed to keep pace with the current application requirement of high speed components. Compared with the amorphous silicon thin film transistor, the polysilicon thin film transistor with the high mobility and low temperature sensitivity is more suitable for the high speed components.

FIG. 1 shows a flow diagram of the traditional preparation of the polysilicon thin film. As shown in FIG. 1, firstly, 101: depositing a metal layer partially covering the surface of the amorphous silicon layer; and then, 102: performing the excimer laser process on the metal layer in order to make metal atoms in the metal material layer be diffused to the amorphous silicon thin film; meanwhile, the metal material layer passes the energy of the excimer laser to the amorphous silicon thin film at the bottom of the metal material layer, which is transformed to the polysilicon thin film, thus forming a polysilicon with a high carrier mobility and improving the electrical conductivity of the polysilicon layer; finally, 103: performing an excimer laser process on the amorphous silicon thin film which is not covered by the metal material layer to convert it into polysilicon thin film.

However, in the process of the second performance of the excimer laser process, when the amorphous silicon in the interface between the metal layer and the amorphous silicon layer is converted into the polysilicon, the metal atoms thereof adjacent to the interface with strong absorption of laser energy lead to the problem that the uniformity of polysilicon thin film in this location is hard to control, thus resulting in the poor uniformity of the prepared polysilicon film and affecting the performance of the products, especially in the products of high uniformity requirements, such as the preparation of AMOLED (active matrix organic light emitting diode decent plate). Compared with the normal display, the display devices with the polysilicon film of poor uniformity will rise the serious chromatism phenomenon, thus reducing the yield of the product and affecting the performance of the product.

In a related technology it has disclosed a method of metal induced crystallization of amorphous silicon, wherein, the first amorphous silicon thin film is desposited on a substrate, the second film is formed on the first one and a pattern is formed on the second film, which consists of the larger area of amorphous silicon exposed area and the smaller exposed amorphous silicon area and the non-exposed area, the thin film containing nickel is deposited on the second thin film and amorphous silicon exposed area, and after the thermal annealing, the amorphous silicon is transformed to the polysilicon film in the process of annealing.

The above related technology can prepare the polysilicon thin film of good quality. However, it did not resolve the problem of the poor uniformity of the polysilicon thin film that was caused by the thermal annealing. The thermal annealing leads to the diffusion of metal atoms to amorphous silicon thin film and the metal atoms in the amorphous silicon thin film is uneven, thus resulting in the poor uniformity of the poly silicon thin film, the reduction of the yield of the product and affecting the performance of the products.

In another related technology it has disclosed a method of low-temperature manufacturing of the polysilicon thin film transistor, wherein, an amorphous silicon layer is formed on a substrate, hydrogen relief treatment is made to the amorphous silicon layer; and another amorphous silicon layer is formed on the amorphous silicon layer whose structure is microgranitic, the hydrogen relief treatment is performed again and its surface becomes microgranulars, the above steps are repeated until the amorphous silicon layer of the multilayer microgranitic shape is formed, and finally, the excimer laser annealing makes it a polysilicon layer, improving the carrier mobility.

However, this related technology can convert the amorphous silicon layer into the polysilicon layer to some extent by depositing the amorphous silicon layer for many times and the laser annealing process finally. However, it did not solve the problems of the incomplete transformation, resulting in the reduction of the yield of the products and affecting the performance of the product.

### SUMMARY OF THE INVENTION

An embodiment of the present disclosure is directed toward a polysilicon layer preparing method capable of improving the performance of the product while effectively avoiding the chromatism problems of the display device, and significantly improving the yield of products.

The method of preparation the polysilicon layer, comprising: forming a plurality of polysilicon thin films on a substrate by the cyclic utilization of the polysilicon deposition and transformation process to form the polysilicon layer covering the upper surface of the substrate; wherein the polysilicon layer is formed by stacking a plurality of the polysilicon thin films in sequence.

According to one embodiment of the present disclosure, wherein the substrate comprises a baseplate, a silicon nitride layer and a silicon oxide layer; wherein, the upper surface of the baseplate is covered by the silicon nitride layer; the upper surface of the silicon nitride layer is covered by the silicon oxide layer; and the upper surface of the silicon oxide layer is covered by the polysilicon layer.

According to one embodiment of the present disclosure, wherein the baseplate is made of glass or plastics.

According to one embodiment of the present disclosure, wherein the polysilicon deposition and transformation process comprises: depositing an amorphous silicon thin film on the baseplate; and transforming the amorphous silicon thin film into the polysilicon thin film.

According to one embodiment of the present disclosure, wherein the amorphous silicon thin film is formed by the chemical vapor deposition, the physical vapor deposition, the plasma enhancing chemical vapor deposition, the low pressure chemical vapor deposition or the atomic layer deposition.

According to one embodiment of the present disclosure, wherein the polysilicon deposition and transformation process comprises the following steps: forming a first polysilicon thin film by a combination of deposition process and transformation process; and performing the combination of deposition process and transformation process on the first polysilicon thin film for N times until the Nth polysilicon thin film is formed; wherein, the upper surface of the substrate is covered by the first polysilicon thin film; an upper surface of the (N−1)th polysilicon thin film is covered by the Nth polysilicon thin film; the number N is a positive integer and N≧2.

According to one embodiment of the present disclosure, wherein the substrate is adopted as the first substrate of depositing a first amorphous silicon thin film during the time of performing the combination of deposition process and transformation process for the first time; and the (N−1)th polysilicon thin film is adopted as the Nth substrate of depositing a Nth amorphous silicon thin film during the time of performing the combination of deposition process and transformation process for the Nth time.

According to one embodiment of the present disclosure, wherein the amorphous silicon thin film is transformed to the polysilicon thin film by the excimer laser process.

According to one embodiment of the present disclosure, wherein the laser intensity of forming the first polysilicon thin film ranges from 200 mJ/cm² to 300 mJ/cm².

According to one embodiment of the present disclosure, wherein the laser intensity of forming the Nth polysilicon thin film ranges from 250 mJ/cm² to 480 mJ/cm².

According to one embodiment of the present disclosure, wherein the laser intensity of forming the Nth polysilicon thin film is greater than that of forming the (N−1)th polysilicon thin film.

According to one embodiment of the present disclosure, wherein the laser intensity of forming the Nth polysilicon thin film is 5 mJ/cm² greater than that of forming the (N−1)th polysilicon thin film.

According to one embodiment of the present disclosure, wherein the thickness of the first polysilicon thin film ranges from 10 nm to 25 nm.

According to one embodiment of the present disclosure, wherein the Nth polysilicon thin film is thicker than the (N−1)th polysilicon thin film.

According to one embodiment of the present disclosure, wherein the thickness of the Nth polysilicon thin film ranges from 15 nm to 35 nm.

According to one embodiment of the present disclosure, wherein the thickness of the polysilicon layer ranges from 25 nm to 35 nm.

### BRIEF DESCRIPTIONS OF THE DRAWINGS

The accompanying drawings, together with the specification, illustrate exemplary embodiments of the present disclosure, and, together with the description, serve to explain the principles of the present disclosure.

FIG. 1 shows a flow diagram of the traditional preparation of the polysilicon thin film;

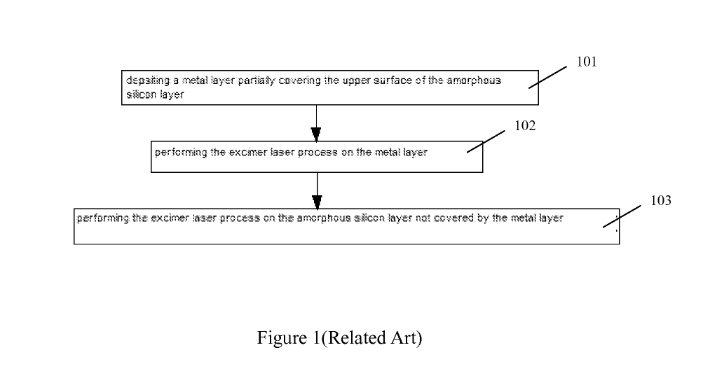

FIG. 2 shows a flow diagram of preparing the polysilicon layer preparation as provided in Embodiment 1 of the present disclosure;

FIG. 3 shows a structure diagram after the deposition of the first the amorphous silicon thin film as provided in Embodiment 2 of the present disclosure;

FIG. 4 shows a structure diagram after the first performance of the excimer laser process as provided in Embodiment 2 of the present disclosure;

FIG. 5 shows a structure diagram after the deposition of the second amorphous silicon thin film as provided in Embodiment 2 of the present disclosure;

FIG. 6 shows a structure diagram after the second performance of the excimer laser process as provided in Embodiment 2 of the present disclosure;

FIG. 7 shows a structure diagram after the deposition of the third amorphous silicon thin film as provided in Embodiment 2 of the present disclosure;

FIG. 8 shows a structure diagram after the third performance of the excimer laser process as provided in Embodiment 2 of the present disclosure.

### DETAILED DESCRIPTIONS

The present disclosure will now be described more fully hereinafter with reference to the accompanying drawings, in which exemplary embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” or “has” and/or “having” when used herein, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

As used herein, “around”, “about” or “approximately” shall generally mean within 20 percent, preferably within 10 percent, and more preferably within 5 percent of a given value or range. Numerical quantities given herein are approximate, meaning that the term “around”, “about” or “approximately” can be inferred if not expressly stated.

As used herein, the term “plurality” means a number greater than one. Hereinafter, certain exemplary embodiments according to the present disclosure will be described with reference to the accompanying drawings.

### Embodiment 1

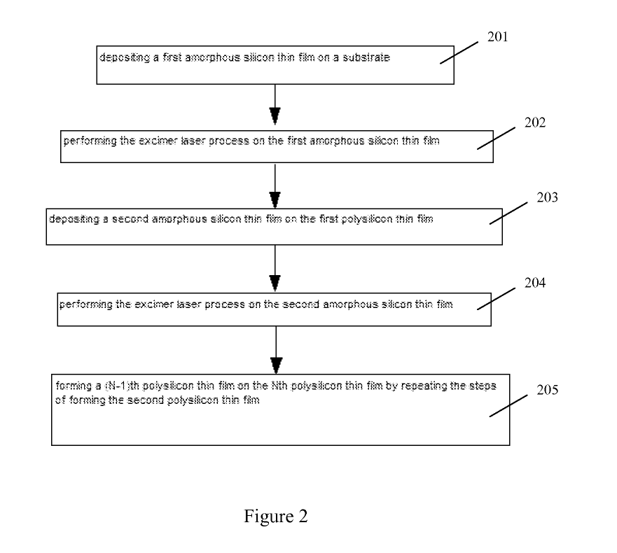

FIG. 2 shows a flow diagram of preparing the polysilicon layer preparation as provided in Embodiment 1 of the present disclosure. Firstly, 201: depositing a first amorphous silicon thin film on a substrate by the method of chemical vapor deposition, 202: performing the excimer laser process on the first amorphous silicon thin film to convert the first amorphous silicon thin film into the first polysilicon thin film; then, 203: depositing a second amorphous silicon thin film on the first polysilicon thin film; next, 204: performing the excimer laser process on the second amorphous silicon thin film to convert the second amorphous silicon thin film into the second polysilicon thin film, after the second amorphous silicon is deposited on the first one by the methods of chemical vapor deposition, physical vapor deposition, plasma enhancing chemical vapor deposition, low pressure chemical vapor deposition and atomic layer deposition; 205: the above steps of preparing the second polysilicon layer are repeated, i.e. the Nth amorphous silicon thin film is deposited on the Nth polysilicon thin film by the methods of chemical vapor deposition, physical vapor deposition, plasma enhancing chemical vapor deposition, low pressure chemical vapor deposition and atomic layer deposition; and then the excimer laser process is performed to convert the Nth amorphous silicon thin film into the Nth polysilicon thin film so that the Nth polysilicon thin film is prepared on the (N−1)th polysilicon thin film, thus forming the polysilicon layer stacked by the first polysilicon thin film, the second polysilicon thin film, . . . , the (N−1)th polysilicon thin film and the Nth polysilicon thin film in sequence. N is a positive integer and N≧2.

The polysilicon deposition and transformation process is composed of the chemical vapor deposition and the excimer laser process. Specifically, an amorphous silicon thin film is deposited and then transformed into the polysilicon thin film. The chemical vapor deposition also can be replaced by the physical vapor deposition, plasma enhancing chemical vapor deposition, low pressure chemical vapor deposition or atomic layer deposition.

Preferably, the substrate includes a baseplate, a silicon nitride layer and a silicon oxide layer. The upper surface of the baseplate is covered by the silicon nitride layer and the upper surface of the silicon nitride layer is covered by the silicon oxide layer. The baseplate is made of glass or plastics. Furthermore, the excimer laser process is performed in the excimer laser device.

Meanwhile, the laser intensity of the preparation of the Nth polysilicon thin film is greater than that of the (N−1)th polysilicon and the laser intensity of preparation of the first polysilicon thin film ranges from 200 mJ/cm² to 300 mJ/cm², such as 200 mJ/cm², 220 mJ/cm², 250 mJ/cm², 280 mJ/cm², 300 mJ/cm². The laser intensity of forming the Nth polysilicon thin film is greater than that of forming the (N−1)th polysilicon thin film and within the scope from 250 mJ/cm² to 480 mJ/cm², such as 250 mJ/cm², 255 mJ/cm², 300 mJ/cm², 445 mJ/cm², 480 mJ/cm². When the laser intensity of forming the (N−1)th polysilicon thin film is 250 mJ/cm², the laser intensity of forming the Nth polysilicon thin film is 255 mJ/cm².

Furthermore, the thickness of first polysilicon thin film ranges from 10 nm to 25 nm, such as 10 nm, 12 nm, 15 nm, 18 nm, 20 nm, 22 nm, 25 nm. The Nth polysilicon thin film is thicker than the (N−1)th polysilicon thin film and the thickness of the Nth polysilicon film is within the scope from 15 nm to 35 nm, such as 15 nm, 16 nm, 27 nm, 34 nm, 35 nm. The thickness of the polysilicon layers sequenced and stacked by the first polysilicon thin film, the second polysilicon thin film, . . . , the (N−1)th polysilicon thin film and the Nth polysilicon thin film ranges from 25 nm to 60 nm, such as 25 nm, 30 nm, 35 nm, 55 nm, 60 nm.

In Embodiment 1 of the present disclosure, by the depositions of the amorphous silicon thin film in batches for many times and the implementation of excimer laser process after each deposition, it can not only convert the amorphous silicon thin film into the polysilicon thin film completely, but also control the uniformity of the polysilicon thin film, thereby gaining the polysilicon layer of good uniformity which composed of the polysilicon thin films stacked in sequence, improving the performance of the product while effectively avoiding the chromatism problems of the display device, and significantly improving the yield of products.

### Embodiment 2

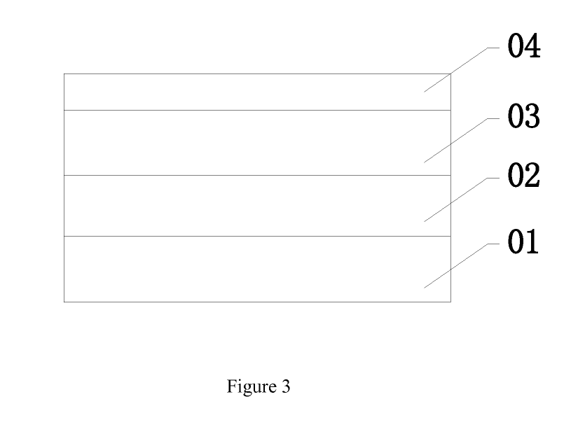

FIG. 3 shows a structure diagram after the deposition of the first the amorphous silicon thin film as provided in Embodiment 2 of the present disclosure. As shown in the figures, a substrate includes a Baseplate 01, a Silicon Nitride Layer 02 and a Silicon Oxide Layer 03. Baseplate 01 is made of glass or plastics, wherein the glass baseplate is preferred. The upper face of Baseplate 01 is covered by Silicon Nitride Layer 02. The upper face of Silicon Nitride Layer 02 is covered by Silicon Oxide Layer 03. A First Amorphous Silicon Thin Film 04 is deposited on the surface of Silicon Oxide Layer 03 by the method of chemical vapor deposition. The thickness of First Amorphous Silicon Thin Film 04 ranges from 10 nm to 25 nm, such as 10 nm, 11 nm, 14 nm, 17 nm, 21 nm, 24 nm, 25 nm.

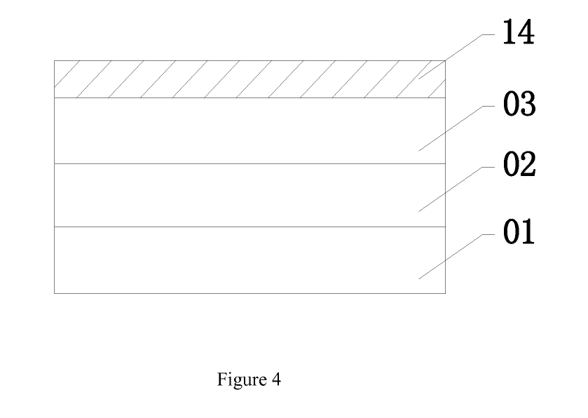

FIG. 4 shows a structure diagram after the first performance of the excimer laser process as provided in Embodiment 2 of the present disclosure. As shown in FIG. 4, after the excimer laser process is performed in the excimer laser device on the surface of

First Amorphous Silicon Thin Film 04, First Amorphous Silicon Thin Film 04 is transformed into First Polysilicon Thin Film 14. The laser intensity of the first performance of excimer laser process ranges from 200 mJ/cm² to 300 mJ/cm², such as 200 mJ/cm², 210 mJ/cm², 245 mJ/cm², 290 mJ/cm², 300 mJ/cm². The thickness of First Polysilicon Thin Film 14 ranges from 10 nm to 25 nm, such as 10 nm, 10.5 nm, 13 nm, 16 nm, 23 nm, 24.5 nm, 25 nm.

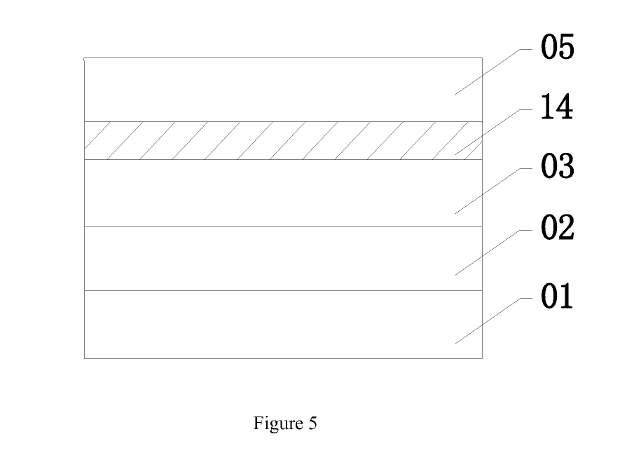

FIG. 5 shows a structure diagram after the deposition of the second amorphous silicon thin film as provided in Embodiment 2 of the present disclosure. A Second Amorphous Silicon Thin Film 05 is deposited on the surface of First Polysilicon Thin Film 14 by the method of chemical vapor deposition. Second Amorphous Silicon Thin Film 05 is thicker than First Amorphous Silicon Thin Film 04. The thickness of Second Amorphous Silicon Thin Film 05 ranges from 15 nm to 35 nm, such as 15 nm, 18 nm, 22 nm, 28 nm, 33 nm, 35 nm. When the thickness of First Amorphous Silicon Thin Film 04 is 15 nm, the thickness of Second Amorphous Silicon Thin Film 05 can be 16 nm, 19 nm, 23 nm, 29 nm, 34 nm, 35 nm and so on.

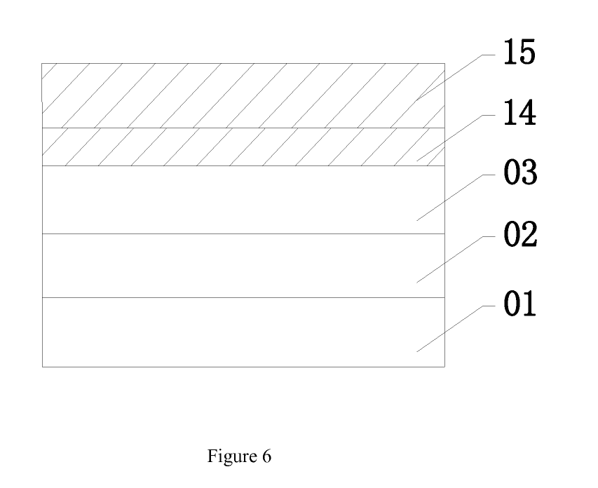

FIG. 6 shows a structure diagram after the second performance of the excimer laser process as provided in Embodiment 2 of the present disclosure. As shown in FIG. 6, after the second excimer laser process is performed in the excimer laser device on the surface of Second Amorphous Silicon Thin Film 05, Second Amorphous Silicon Thin Film 05 is transformed into Second Polysilicon Thin Film 15. The laser intensity of the second performance of the excimer laser process is greater than that of the first one. The laser intensity of the second performance of the excimer laser process ranges from 250 mJ/cm ² to 480 mJ/cm², such as 250 mJ/cm², 300 mJ/cm², 375 mJ/cm², 425 mJ/cm², 480 mJ/cm². When the laser intensity of the first excimer laser process is 260 mJ/cm², the laser intensity of the second one is 265 mJ/cm². The thickness of Second Polysilicon Thin Film 15 is thicker than that of First Polysilicon Thin Film 14. The thickness of Second Polysilicon Thin Film 15 ranges from 15 nm to 35 nm, such as 15 nm, 19 nm, 25 nm, 29 nm, 34 nm, 35 nm. When the thick of First Polysilicon Thin Film 14 is 15 nm, the thickness of Second Polysilicon Thin Film 15 can be 16 nm, 21 nm, 27 nm, 32 nm, 34 nm, 35 nm and so on.

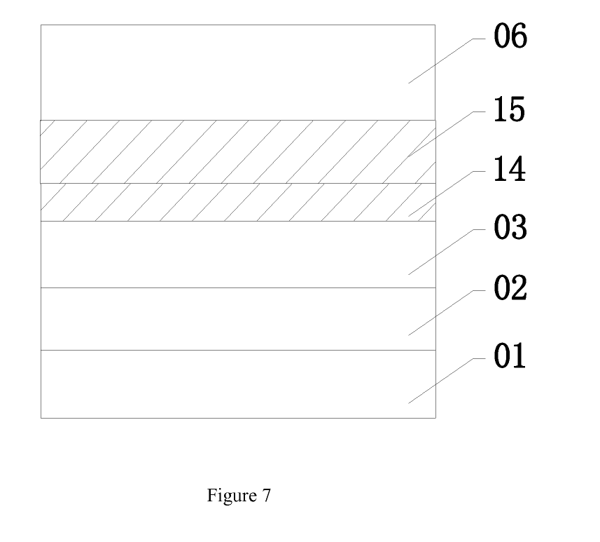

FIG. 7 shows a structure diagram after the deposition of the third amorphous silicon thin film as provided in Embodiment 2 of the present disclosure. As shown in FIG. 7, a Third Amorphous Silicon Thin Film 06 is deposited on the surface of the Second Polysilicon Thin Film 15 by the method of the chemical vapor deposition, physical vapor deposition, plasma enhancing chemical vapor deposition, low pressure chemical vapor deposition and atomic layer deposition. The thickness of Third Amorphous Silicon Thin Film 06 is thicker than that of Second Amorphous Silicon Thin Film 05. The thickness of Third Amorphous Silicon Thin Film 06 ranges from 15 nm to 35 nm, such as 15 nm, 17 nm, 20 nm, 25 nm, 31 nm, 35 nm and so on. When the thickness of Second Amorphous Silicon Thin Film 05 is 20 nm, the thickness of Third Amorphous Silicon Thin Film 06 can be 21 nm, 24 nm, 28 nm, 31 nm, 34 nm, 35 nm and so on.

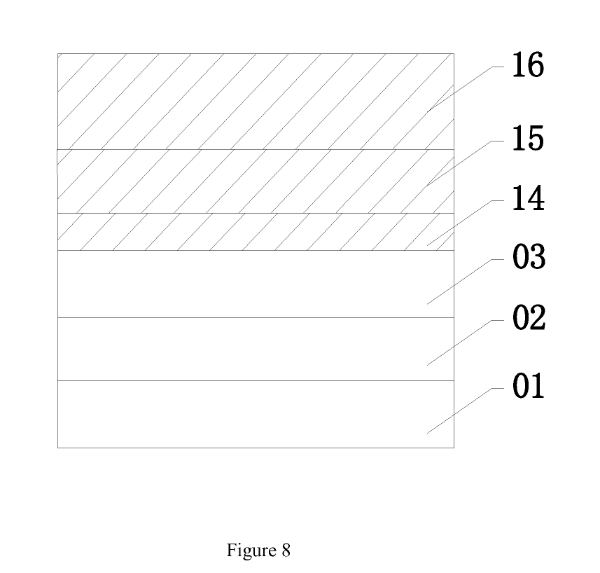

FIG. 8 shows a structure diagram after the third performance of the excimer laser process as provided in Embodiment 2 of the present disclosure. As shown in FIG. 8, after the third excimer laser process is performed in the excimer laser device on the surface of Third Amorphous Silicon Thin Film 06, Third Amorphous Silicon Thin Film 06 is transformed into Third Polysilicon Thin Film 16. The laser intensity of the third performance of the excimer laser process on Third Amorphous Silicon Thin Film 06 is greater than that of the second one. The laser intensity of the third performance of excimer laser process ranges from 250 mJ/cm² to 450 mJ/cm², such as 250 mJ/cm², 270 mJ/cm², 305 mJ/cm², 345 mJ/cm², 445 mJ/cm², 480 mJ/cm². When the laser intensity of the second excimer laser process is 300 mJ/cm², the laser intensity of the third one can be 305 mJ/cm². Third Polysilicon Thin Film 16 is thicker than Second Polysilicon Thin Film 15. The thickness of Third Polysilicon Thin Film 16 ranges from 15 nm to 35 nm, such as 15 nm, 18 nm, 24 nm, 27 nm, 33 nm, 35 nm. When the thickness of Second Polysilicon Thin Film 15 is 23 nm, Third Polysilicon Thin Film 16 can be 24 nm, 32 nm, 36 nm, 37 nm, 39 nm, 40 nm and so on.

Meanwhile, a polysilicon layer is stacked by First Polysilicon Thin Film 14, Second Polysilicon Thin Film 15 and Second Polysilicon Thin Film 16 in sequence. The thickness of polysilicon layer ranges from 25 nm to 60 nm, such as 25 nm, 26 nm, 33 nm, 58 nm, 60 nm.

In Embodiment 2 of the present disclosure, by the depositions of the amorphous silicon thin film in batches for many times and the implementation of excimer laser process after each deposition, it can not only convert the amorphous silicon thin film into the polysilicon thin film completely, but also control the uniformity of the polysilicon thin film, thereby gaining the polysilicon layer of good uniformity, improving the performance of the product while effectively avoiding the chromatism problems of the display device, and significantly improving the yield of products.

While the present disclosure has been described in connection with certain exemplary embodiments, it is to be understood that the invention is not limited to the disclosed embodiments, but, on the contrary, is intended to cover various modifications and equivalent arrangements included within the spirit and scope of the appended claims, and equivalents thereof

What is claimed is:

1. A polysilicon layer preparing method comprising the steps of:
forming a plurality of polysilicon thin films on a substrate by polysilicon deposition and transformation process;
wherein, the polysilicon layer is formed by stacking a plurality of the polysilicon thin films in sequence.

2. The method as claimed in claim 1, wherein the substrate comprises a baseplate, a silicon nitride layer and a silicon oxide layer;
wherein, an upper surface of the baseplate is covered by the silicon nitride layer; an upper surface of the silicon nitride layer is covered by the silicon oxide layer; and an upper surface of the silicon oxide layer is covered by the polysilicon layer.

3. The method as claimed in claim 2, wherein the baseplate is made of glass or plastic.

4. The method as claimed in claim 1, wherein the polysilicon deposition and transformation process comprises:
depositing an amorphous silicon thin film on the baseplate; and
transforming the amorphous silicon thin film into the polysilicon thin film.

5. The method as claimed in claim 4, wherein the amorphous silicon thin film is formed by chemical vapor deposition, physical vapor deposition, plasma enhancing chemical vapor deposition, low pressure chemical vapor deposition or atomic layer deposition.

6. The method as claimed in claim 4, wherein the polysilicon deposition and transformation process comprises the following steps:
forming a first polysilicon thin film by a combination of deposition process and transformation process; and
performing the combination of deposition process and transformation process on the first polysilicon thin film for N times until the Nth polysilicon thin film is formed;
wherein, the upper surface of the substrate is covered by the first polysilicon thin film; an upper surface of the (N−1)th polysilicon thin film is covered by the Nth polysilicon thin film; the number N is a positive integer and N≧2.

7. The method as claimed in claim 6, wherein the substrate is adopted as the first substrate of depositing a first amorphous silicon thin film during the time of performing the combination of deposition process and transformation process for the first time; and
the (N−1)th polysilicon thin film is adopted as the Nth substrate of depositing a Nth amorphous silicon thin film during the time of performing the combination of deposition process and transformation process for the Nth time.

8. The method as claimed in claim 6, wherein the amorphous silicon thin film is transformed to the polysilicon thin film by the excimer laser process.

9. The method as claimed in claim 8, wherein the laser intensity of forming the first polysilicon thin film ranges from 200 mJ/cm² to 300 mJ/cm².

10. The method as claimed in claim 8, wherein the laser intensity of forming the Nth polysilicon thin film ranges from 250 mJ/cm² to 480 mJ/cm².

11. The method as claimed in claim 8, wherein the laser intensity of forming the Nth polysilicon thin film is greater than that of forming the (N−1)th polysilicon thin film.

12. The method as claimed in claim 8, wherein the laser intensity of forming the Nth polysilicon thin film is 5 mJ/cm² greater than that of forming the (N−1)th polysilicon thin film.

13. The method as claimed in claim 6, wherein the thickness of the first polysilicon thin film ranges from 10 nm to 25 nm.

14. The method as claimed in claim 6, wherein the Nth polysilicon thin film is thicker than the (N−1)th polysilicon thin film.

15. The method as claimed in claim 6, wherein the thickness of the Nth polysilicon thin film ranges from 15 nm to 35 nm.

16. The method as claimed in claim 6, wherein the thickness of the polysilicon layer ranges from 25 nm to 35 nm.
